(19) United States
(12) Patent Application Publication
(10) Pub. No.: US 2026/0156961 A1
(43) Pub. Date: Jun. 4, 2026

(54) METHOD OF MANUFACTURING A MICROELECTRONIC DEVICE

(71) Applicant: Commissariat à I'Énergie Atomique et aux Énergies Alternatives, Paris (FR)

(72) Inventors: Amélie Bellemin Comte, Grenoble (FR); Léopold Virot, Grenoble (FR); Clément Castan, Grenoble (FR); Stéphanie Garcia, Grenoble (FR); Floriane Baudin, Grenoble (FR); Gabriel Lima, Grenoble (FR); Julian Sturm, Grenoble (FR); Amélie Lambert, Grenoble (FR)

(73) Assignee: Commissariat à I'Énergie Atomique et aux Énergies Alternatives, Paris (FR)

(21) Appl. No.: 19/406,091

(22) Filed: Dec. 2, 2025

(30) Foreign Application Priority Data
Dec. 3, 2024 (FR) FR2413335

(51) Int. Cl. H10F 71/00; H10F 30/223; H10F 77/122; H10F 77/1226; H10F 77/40

(52) U.S. Cl. CPC H10F 71/1212; H10F 30/223; H10F 77/122; H10F 77/1226; H10F 77/413

(57) ABSTRACT

A method of manufacturing a microelectronic device including the following steps: a) providing a substrate, a cavity being formed from a first main surface of the substrate, the bottom of the cavity being made of a first material, the first main surface being made of a second material, b) performing a selective epitaxy of a third material in the cavity to form an epitaxial structure filling and protruding out of the cavity by a so-called protrusion thickness, c) depositing an encapsulation layer made of a fourth material on the substrate and the epitaxial structure, d) carrying out a CMP thinning step to remove the encapsulation layer and the portion of the epitaxial material protruding from the first main surface, the thickness of the deposited encapsulation layer being in the range from 20 to 200% of the protrusion thickness.

### CROSS REFERENCE TO RELATED APPLICATIONS

This application claims priority to French application number 2413335, filed Dec. 3, 2024. The contents of this application is incorporated by reference in its entirety.

### Technical Field

The present disclosure generally concerns the field of microelectronics, and more specifically the manufacturing of microelectronic devices requiring the implementation of a local selective epitaxy step followed by a planarization step.

The invention is particularly advantageous for the forming of photodiodes, electro-absorption modulators, or also lasers made of germanium, GeSn, or SiGe on silicon.

### Prior Art

To manufacture certain microelectronic devices, for example photodiodes, it is sometimes necessary to selectively grow germanium by epitaxy in a cavity, the bottom of which is a silicon crystal substrate. For this purpose, a mask made of a material on which germanium does not grow is deposited on a silicon substrate. The mask is, for example, made of SiO₂. So-called seed windows are formed in the mask, by etching, to locally expose the silicon surface. During the etch step, the silicon can also be etched in order to create cavities in the substrate.

The germanium growth is then achieved in cavities. The sides of the cavities comprise SiO₂ and Si in cases where the substrate has been etched.

To obtain photodiodes having an optimized performance, the formed cavity needs to be filled, but the germanium should not protrude from the cavity.

There exist three methods for achieving non-protruding silicon epitaxy.

First, as described in reference [1], the epitaxy is leveling. However, this method is not feasible when the substrate comprises cavities of different sizes and/or depths, since the growth rate is different according to the size of the cavities. To remove germanium islands protruding from the surface of the silicon substrate, a peroxide and water solution can be used in order to smooth the surface of the photodiode, as described in reference [2].

A second method consists of performing an epitaxy protruding out of the cavities, then carrying out a step of planarization, for example by chemical-mechanical polishing (CMP), to remove the protruding germanium portion. For a same device comprising different cavity sizes, the germanium can protrude by a height of from 300 nm to over 1 μm. However, during the planarization step, the mechanical effect which is exerted on these structures causes a tearing away of germanium, which creates planarization defects and the epitaxial material may be deteriorated [3, 4].

A last method comprises depositing, after selective epitaxy, a thin layer of another material (for example, SiO₂ or SiN) to protect the germanium during the CMP step to prevent its alteration. This method also enables to fill the cavity edges when the epitaxy is not totally protruding [5]. However, the cavity is not filled with germanium only, which may decrease the optical properties of the device.

### SUMMARY OF THE INVENTION

There exists a need for a method of manufacturing a microelectronic device, enabling to have a high-quality epitaxial material in a cavity.

This aim is achieved by a method of manufacturing a microelectronic device, for example a photonic device, particularly a photodiode, comprising the following steps:
a) providing a substrate comprising a cavity formed from a first main surface of the substrate, the bottom of the cavity being made of a first material, the first main surface of the substrate being made of a second material,
b) performing a selective epitaxy of a third material in the cavity of the substrate, until the epitaxial material fills the cavity and protrudes out of the cavity by a so-called protrusion thickness, whereby an epitaxial structure is obtained,
c) depositing an encapsulation layer made of a fourth material on the substrate and on the epitaxial structure,
d) carrying out a CMP thinning step to remove the encapsulation layer and the portion of the epitaxial structure protruding from the first main surface of the substrate, the thickness of the deposited encapsulation layer being in the range from 20 to 200% of the protrusion thickness.

According to a specific embodiment, the thickness of the encapsulation layer is in the range from 20 to 100%, preferably from 20 to 50%, of the protrusion thickness.

According to a specific embodiment, the bottom of the cavities is made of a semiconductor material, preferably monocrystalline, and even more preferably single-crystal silicon.

According to a specific embodiment, the encapsulation layer is made of silicon oxide, the encapsulation layer being preferably deposited by PECVD.

According to a specific embodiment, the second material is silicon oxide.

According to a specific embodiment, the third material is a semiconductor material, preferably germanium or one of its alloys, for example GeSn or SiGe.

According to a specific embodiment, the substrate comprises a plurality of cavities with different or identical dimensions.

According to a specific embodiment, the cavities have different dimensions and step b) is carried out until the epitaxial material protrudes out of all cavities.

According to a specific embodiment, a stop layer, for example made of SiN, is arranged in the substrate and the thinning step is stopped when the stop layer is reached.

This aim is also achieved by a microelectronic device, for example a photonic device, comprising a substrate, a cavity being formed from a first main surface of the substrate, the bottom of the cavity being made of a first material, the first main surface of the substrate being made of a second material, the cavity being totally filled with a third epitaxial semiconductor material.

According to a specific embodiment, the bottom of the cavity is made of single-crystal silicon, the second material is silicon oxide, and the third epitaxial material is SiGe, GeSn, or Ge.

According to a specific embodiment, the device is a photodiode.

### BRIEF DESCRIPTION OF THE DRAWINGS

These features and advantages, as well as others, will be described in detail in the following description of specific embodiments, which is provided by way of example and is not intended to be limiting, in connection with the accompanying drawings, in which:

FIG. 1A, FIG. 1B, FIG. 1C, and FIG. 1D schematically show different steps of a microelectronic device manufacturing method, according to a specific embodiment of the invention;

FIG. 2A, FIG. 2B, FIG. 2C, and FIG. 2D schematically show different steps of a microelectronic device manufacturing method, according to another specific embodiment of the invention;

FIG. 3A, FIG. 3B, FIG. 3C, and FIG. 3D schematically show different steps of a microelectronic device manufacturing method, according to another specific embodiment of the invention;

FIG. 4 schematically shows, in cross-section, a photonic device, according to another specific embodiment of the invention;

FIG. 5A, FIG. 5B, and FIG. 5C are images obtained with a scanning electron microscope (SEM) of a modulator during different stages of its manufacturing method, respectively, after selective epitaxy of SiGe, after encapsulation with SiO₂, and after CMP thinning of the SiGe and of the SiO₂ encapsulation layer, according to another specific embodiment of the invention;

FIG. 6 is an SEM image of a modulator after CMP thinning of the SiGe, according to an example given for comparison purposes;

FIG. 7A, FIG. 7B, and FIG. 7C are SEM images of different photodiodes on 300-mm substrates after CMP thinning of the SiGe and of the SiO₂ encapsulation layer, according to another specific embodiment of the invention;

FIG. 8A and FIG. 8B are SEM images of different photodiodes on 200-mm substrates after CMP thinning of the SiGe and of the SiO₂ encapsulation layer, according to another specific embodiment of the invention;

FIG. 9 is an SEM image of a photodiode on a 300-mm substrate after CMP thinning of the SiGe, according to an example given for comparison purposes.

The various elements are not necessarily shown to a uniform scale, to make the drawings more readable.

### DESCRIPTION OF EMBODIMENTS

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and have been described in detail.

Unless otherwise specified, when reference is made to two elements being connected to each other, this means directly connected without any intermediate elements other than conductors, and when reference is made to two elements being coupled to each other, this means that these two elements may be connected or may be connected via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

By in the range from X to Y, there is meant that limits X and Y are included.

In the drawings, a single cavity is shown in the substrate for better readability, but a plurality of cavities may be formed in a same substrate.

The method which will be described hereafter is particularly advantageous to manufacture a microelectronic device, preferably a photonic devices, particularly a photodiode. Hereafter, even though the disclosure more particularly mentions a photodiode manufacturing method, the method may be used to manufacture other devices, for example lasers, particularly made of germanium or SiGe integrated on silicon, or electro-absorption modulators.

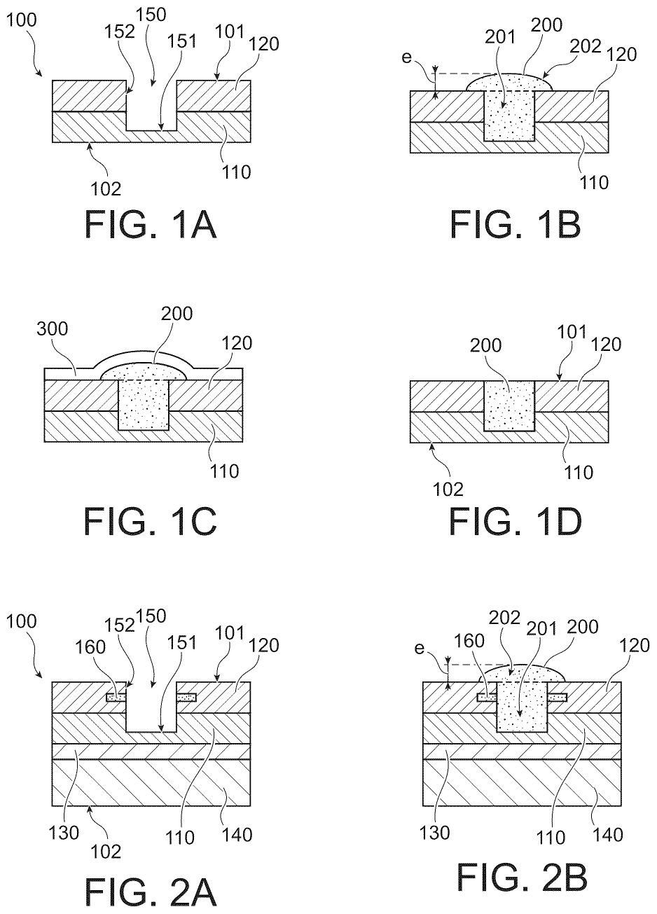

The device manufacturing method will now be described with reference to FIGS. 1A to 1D, FIGS. 2A to 2D, FIGS. 3A to 3D, and FIG. 4. The method comprises at least the following steps:
a) providing a substrate 100 comprising a cavity 150 formed from a first main surface 101 of substrate 100, the bottom 151 of cavity 150 being made of a first material, the first surface 101 of substrate 100 being made of a second material (FIGS. 1A, 2A, 3B),
b) performing a selective epitaxy of a third material in the cavity 150 of substrate 100, until the epitaxial material fills cavity 150 and protrudes out of cavity 150, whereby an epitaxial structure 200 is obtained, comprising a first portion 201 filling cavity 150 and a second portion 202 locally covering the first main surface 101 of substrate 100 at the periphery of cavity 150 and protruding from the first main surface 101 of substrate 100 by a so-called protrusion thickness (FIGS. 1B, 2B, 3C),
c) depositing an encapsulation layer 300 made of a fourth material on substrate 100 and on epitaxial structure 200, the thickness of the deposited encapsulation layer 300 being in the range from 20 to 200%, preferably from 20 to 100%, and even more preferably from 20 to 50% (for example, 30%) of the protrusion thickness (FIGS. 1C, 2C, 3D),
d) carrying out a step of thinning by chemical-mechanical polishing (CMP) to remove portion 202 of epitaxial structure 200 protruding from the first main surface 101 of substrate 100 (FIGS. 1D, 2D, 3D).

The method implements both a step of encapsulation of a protruding epitaxial structure 200 and a planarization step. This method is particularly advantageous.

With such a method, it is possible to fill cavities 150 having dimensions ranging from a few hundred nm to several tens of micrometers, since if the epitaxial material protrudes out of the cavities, it is easily removed, conversely to certain methods of prior art.

The planarization step enables to both thin encapsulation layer 300 and protruding epitaxy 200 at the same rate. The thickness of encapsulation layer 300 is preferably smaller than the thickness of the step to be planarized. There is no need to deposit a thickness greater than that of the step which is desired to be planarized, since it is not necessary to be already planar at the beginning of the CMP. This decreases the non-uniformity of the surface after planarization (a parameter dependent on the thicknesses to be consumed). In the method, the non-uniformity which may result from the CMP process is minimized since, even depositing an encapsulation layer 300 having a thickness twice smaller than that of the step to be planarized, both materials are consumed at the same rate.

By decreasing the deposited thickness, the uniformity of the CMP step is improved. This enables to decrease the thickness of the epitaxial material at closest to the substrate.

During the manufacturing of a photodiode, the germanium growth which significantly protrudes from the cavity is planarized as close as possible to the height of the guide (approximately 40 nm). Risks of tearing are eliminated due to the encapsulation of the epitaxial material. The CMP thinning remains controlled because the encapsulation thickness is much lower than the overflow of the epitaxial material. This enables to improve the component performance.

Finally, in the case of a photodiode, there is no faceting of the third material, which would be detrimental to its operation, in particular by causing significant losses of the optical signal by reflections on the facets.

The different steps of the method will now be described in more detail.

The substrate 100 provided at step a) comprises a first main surface 101 and a second main surface 102. At least one cavity 150 is formed from the first main surface 101 of substrate 100. By at least one, there is meant that one cavity 150 or a plurality of cavities 150 may be formed from the first main surface 101.

Cavities 150 may have identical or different dimensions. The dimensions of cavities 150 are, for example, in the range from a few hundred nanometers to several tens of micrometers.

Hereafter, one cavity 150 will be more particularly described, but what is described for said cavity may apply to other cavities which would be in substrate 100.

Cavity 150 comprises a bottom 151 and a side wall 152. It is a hole opening onto the first main surface 101 of substrate 100.

The bottom 151 of cavity 150 is made of a first material configured to allow the beginning of the growth of the third material by epitaxy. It plays the role of a seed layer. The first material is preferably a semiconductor material, more preferably a crystalline, more particularly single crystal, semiconductor. It is, for example, single crystal silicon.

The first main surface 101 of substrate 100 is made of a second material which does not allow the growth of the third material by epitaxy. During step b), the epitaxial material does not grow from the first surface 101 of substrate 100. The epitaxy of the third material is thus selective.

Preferably, at least the upper part of the side wall 152 (or flank) of cavity 150 is made of a second material, to prevent the growth of the epitaxial material from the top of cavity 150. The lower part of the side wall 151 may be made of the first material. This will favor the beginning of the growth of the epitaxial material from the bottom of cavity 150.

By upper part of cavity 150, there is meant the part of cavity 150 closest to the first surface 101. By lower part of cavity 150, there is meant the part of cavity 150 closest to the bottom 151 of cavity 150.

The upper part may be at least 40-nm thick.

Alternatively, the entire side wall 152 is made of first material or of second material.

For example, in the case of selective germanium or SiGe epitaxy, the bottom 151 of cavity 150 is made of silicon and the first main surface 101 of substrate 100 is made of silicon oxide. The growth is selective over silicon.

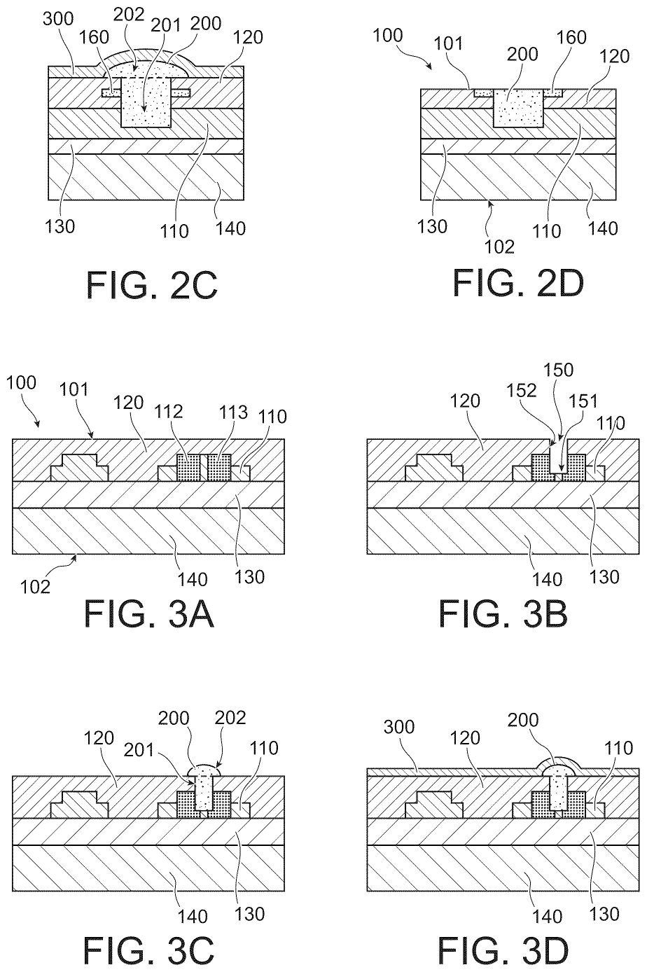

According to a specific embodiment, for example shown in FIGS. 2A to 2D, 3A to 3D, and 4, substrate 100 may be formed from an SOI (“Silicon on Insulator”) substrate covered with an oxide passivation layer 120, that is, substrate 100 successively comprises a silicon support substrate 140, a silicon oxide layer 130 (BOX), a single-crystal silicon layer 110, and passivation layer 120. The cavity 150 formed in this substrate 100 extends through passivation layer 120 and opens into silicon layer 110. The growth thus starts on a crystalline Si seed. Passivation layer 120 prevents the growth of germanium on the first main surface 101 of substrate 100 (where Ge should not grow). The upper part of the flanks 152 of cavity 150 are made of silicon oxide in order to prevent the growth of Ge from this part of the flanks. Cavities 150 may be formed by photolithography.

For certain applications, a waveguide may be formed in the substrate. More specifically, the guide is formed in SOI layer 110.

According to an alternative embodiment, the substrate is formed of a plurality of layers. A difference in index between the core and the sheath enables to form a waveguide.

As shown in FIGS. 3A to 3D and 4, silicon layer 110 may be structured and/or doped. In particular, cavity 150 may be positioned between a first n-doped silicon portion 112 and a second p-doped silicon portion 113. The photodiode is a silicon-germanium-silicon double heterojunction photodiode comprising a horizontal stack comprising an n-doped silicon layer 112, an intrinsic germanium layer 200, and a p-doped silicon layer 113.

Before growth step b), it is possible to carry out a pretreatment step. It may be a step of cleaning (for example by means of a hydrofluoric acid solution) and/or of heat treatment (for example, an anneal at a temperature in the range from 750 to 1,000° C. under hydrogen). The pretreatment enables to obtain a surface suitable for growth.

During step b), the third material is epitaxially grown. It may be epitaxially grown, for example, by ultra-high vacuum chemical vapor deposition (UHV-CVD). The growth may be carried out at a temperature, for example, in the range from 300 to 750° C. The temperature is selected so as to accommodate the difference in lattice parameter between the first material and the third material with no forming of islands, and thus obtain epitaxial layers of good crystalline quality. The growth may be a growth in two steps at two temperatures (a low temperature, for example in the range from 300 to 450° C., and a high temperature, for example in the range from 600 to 800° C.). The pressure is, for example, in the range from 10 to 150 torr (that is, from 1,333.22 to 19,998.4 Pa).

Since the growth is not perfectly planar, it is possible to observe, during the growth, different facets of the Ge crystal. The growth of the epitaxial material is continued until having it overflow from cavity 150. This enables to improve the quality of the material, in particular by reducing dislocations in the Ge layer. For optical applications, and in particular in the case of a photodiode, this enables not to degrade the coupling of light by multiple reflections.

Epitaxial structure 200 has a mushroom-shaped structure. A first portion 201 of structure 200 completely fills cavity 150, and a second portion 202 of structure 200 covers the first portion 201 and extends over the first main surface 101 of substrate 100.

The protruding portion 202 of structure 200 has a so-called protrusion thickness ‘e’. Protrusion thickness e corresponds to the greatest thickness which protrudes from the first surface 101 of substrate 100. The overhang thickness of the third epitaxial material depends on the dimensions of the devices. It is necessary to perform a protruding epitaxy to fill each cavity. The largest cavities take longer to fill, whereby small cavities will have a greater protrusion thickness. The thickness of encapsulation layer 300 then depends on the greatest protrusion thickness.

The disclosure more particularly mentions a selective germanium epitaxy in cavities having a silicon bottom and a silicon oxide encapsulation layer. Other materials may be used instead of germanium: for example, a silicon alloy, in particular SiGe (having, for example, up to atomic 30% of Si) or GeSn (having, for example, up to atomic 10% of Sn). Similarly, other combinations of materials may be used, such as for example silicon and silicon oxide, polysilicon, and silicon oxide. It is also possible to encapsulate copper with silicon oxide, the CMP then being a CMP on SiO₂ and copper. Copper may be deposited by electrochemical deposition (ECD).

After the growth step, an encapsulation layer 300 is deposited so as to cover at least epitaxial structure 200 and preferably the first main surface of substrate 100 (step c)). Encapsulation layer 300 is preferably deposited over the entire wafer.

Encapsulation layer 300 may be deposited, for example, by plasma-enhanced chemical vapor deposition (PECVD).

It is a layer 300 playing the role of a sacrificial layer. This encapsulation layer 300 decreases the mechanical action exerted on the epitaxial material and prevents tearing.

Sacrificial layer 300 also enables to address protrusions by different thicknesses obtained during a same epitaxy step for cavities of different sizes.

Encapsulation layer 300 has a thickness in the range from 20 to 200% of the protrusion thickness.

The thickness of encapsulation layer 300 is preferably in the range from 20 to 100%, and even more preferably from 20 to 50%, and most preferably from 20 to 40% (for example, approximately 30%) of the protrusion thickness.

Encapsulation layer 300 is made of a fourth material. It is preferably made of a same material as that of the passivation layer. The fourth material is, for example, SiO₂, particularly in the case of an epitaxy of germanium or of one of its alloys (SiGe, GeSn).

During step d), a CMP step is then implemented (step d). This step results in the obtaining of a planar surface. This step is non-selective. It enables to polish both the encapsulation layer 300 deposited at step c) and epitaxial structure 200. The materials are thinned simultaneously and at the same rate. It is thus possible to come, in the case of a photodiode, as close as possible to the silicon guide in order to limit the thickness of the photodiode. This enables to decrease the response time in the case of vertical or lateral photodiodes. Decreasing the thickness of germanium therefore enables to improve the performance of photodiodes.

As shown in FIGS. 2A to 2D and in FIG. 4, substrate 100 may comprise a stop layer 160. Stop layer 160 is positioned in a plane parallel to the bottom 151 of cavities 150. It is arranged between the bottom 151 of cavities 150 and the first main surface 101 of substrate 100. Cavity 150 may extend through barrier layer 160. For example, in the case of a photodiode, it is possible to integrate stop layer 160 between the waveguide and the first main surface 101 of substrate 100 in order to improve the stopping of the thinning and to further decrease the non-uniformity of the planarization method.

With such a method, a very good uniformity can be achieved over large surface areas, and in particular over an entire plate (for example, with a uniformity around 2% across the thickness of the barrier layer).

Stop layer 160 is separated from the first material by the smallest possible thickness, for example, by a thickness in the range from 10 to 20 nm. Stop layer 160 may be in contact with the first material.

Stop layer 160 may be made of SiN. Depending on the different materials of the substrate and on the epitaxial material, it is also possible to select stop layers on SiC or SiO₂.

At the end of step d), the method may comprise subsequent steps, for example steps of encapsulation and/or contact forming on p area 113 and n area 112. These steps may be carried out by means of etching, filling, and CMP steps. The thinner the device, the smaller the contacting areas can be.

The resulting device comprises a substrate 100 having a first main surface 101 and a second main surface 102, a cavity 150 being formed from the first main surface 101 of substrate 100. The bottom 151 of cavity 150 is made of a first material, preferably semiconductor. The first main surface 101 of substrate 100 is made of a second material. Cavity 150 is completely filled with a third epitaxial semiconductor material 200 (in other words, there are no other materials in cavity 150).

The first semiconductor material and the third semiconductor material are preferably crystalline materials, more preferably single-crystal semiconductor materials.

Substrate 100 comprises, for example, successively: a silicon support substrate 140, a silicon oxide layer 130 (“BOX”), and a silicon layer 110 capable of being structured and/or doped, and a passivation layer 120.

### Epitaxial Material 200 Is Preferably Germanium, Gesn, or Sige.

Epitaxial material 200 may be arranged between a first n-doped silicon portion (Si−) 112 and a second p-doped silicon portion (Si+) 113 to form a PIN photodiode. Epitaxial material 200 is the intrinsic material in the PIN photodiode. The photodiode is a double heterojunction photodiode.

The absorption area of the photodiode corresponds to the epitaxial germanium. This absorption area is an area configured to absorb at least partly the light flux and generate electrical charges.

The photodiode may be coupled to a waveguide. The coupling may be an evanescent coupling. For example, the coupling can be achieved in evanescent manner with a waveguide formed in SOI layer 110 and the germanium which is epitaxially grown on top of it. It is also possible to have a direct coupling with a waveguide formed in layer 110 when the cavity is etched in SOI layer 110.

### Illustrative and Non-Limiting Example

In This First Example, a Modulator Was Manufactured.

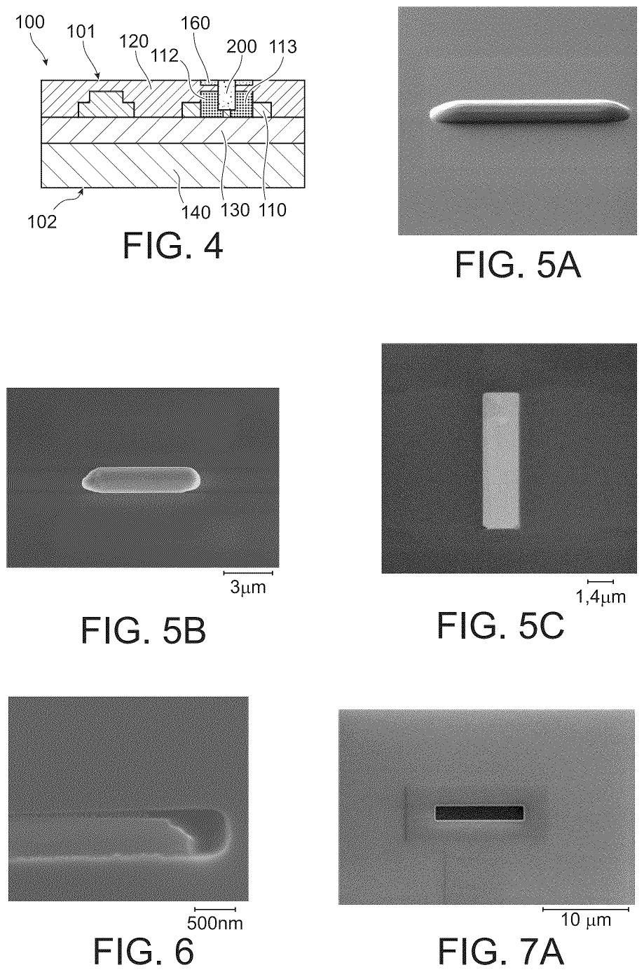

After having performed a selective protruding epitaxy of germanium in a cavity having a silicon bottom (FIG. 5A), the germanium was encapsulated by a SiO₂ encapsulation layer (FIG. 5B), after which a non-selective CMP step (FIG. 5C) was implemented.

As a comparison, a modulator was manufactured according to the following steps:
performing a selective epitaxy of germanium in cavities of different sizes, then carrying out the planarization step. In the comparative example, there is no encapsulation step. The resulting device shows signs of tearing (FIG. 6).

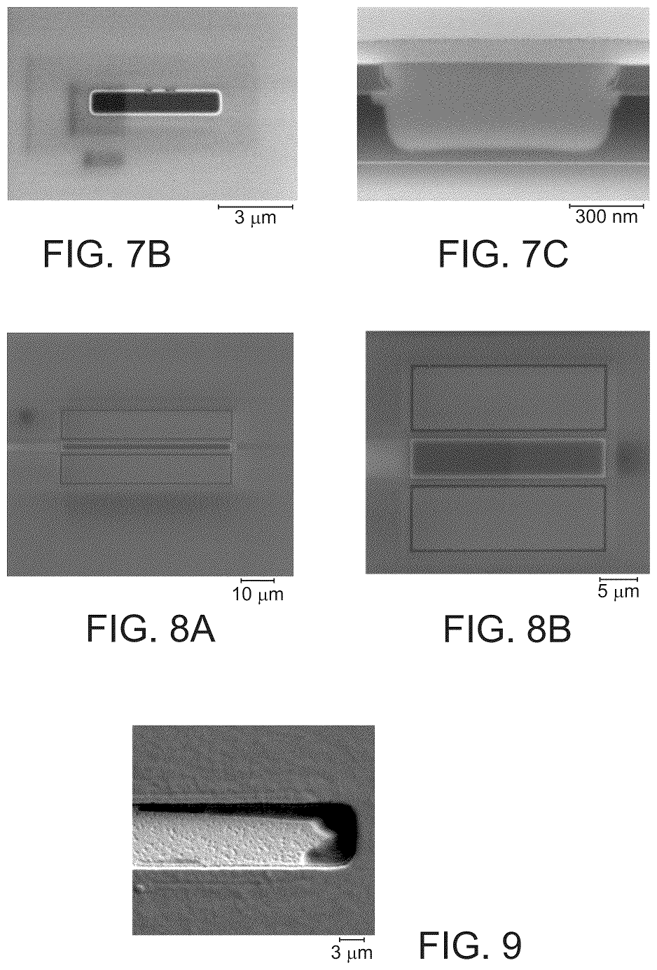

Photodiodes were manufactured on 300-mm substrates (FIGS. 7A, 7B, and 7C) and 200-mm substrates (FIGS. 8A and 8B). A plurality of different masks were tested. Photodiodes ranging from 300-nm wide to some hundred microns wide could thus be manufactured.

SEM observations show that the structure of the photodiodes is free of defects.

As a comparison, photodiodes were manufactured without depositing encapsulation layers. After CMP, tear marks are visible (FIG. 9).

This confirms that it is thanks to the presence of the encapsulation layer, deposited before CMP, that the germanium shows no tear marks.

The main performance characteristics obtained with this method are the following:
a local topography after CMP smaller than 20 nm,
an oxide thickness after thinning by CMP of at least 50 nm.

Various embodiments and variants have been described. The person skilled in the art will understand that certain features of these various embodiments and variants could be combined, and other variants will become apparent to the person skilled in the art.

Finally, the practical implementation of the described embodiments and variants is within the abilities of those skilled in the art based on the functional indications given hereabove.

### REFERENCES

[1] Ryzhak et al., “Selective Epitaxy of Germanium on Silicon for the Fabrication of CMOS-Compatible Short-Wavelength Infrared Photodetectors,” Mater. Sci. Semicond. Process. (2024), 176, 108308
[2] US 2010/0151619 A1
[3] Bae et al., “Chemical mechanical planarization mechanism of epitaxially grown Ge-film for sequential integrating 3D-structured transistor cells,” J. Korean Phys. Soc. (2022), 81, 12, 1262-1268
[4] JP 6696735 B2
[5] WO 2020/096620 A1

1. Method of manufacturing a microelectronic device, for example a photonic device, particularly a photodiode, comprising the following steps:
a) providing a substrate comprising a cavity formed from a first main surface of the substrate, a bottom of the cavity being made of a first material, the first main surface of the substrate being made of a second material,
b) performing a selective epitaxy of a third material in the cavity of the substrate, until the epitaxial material fills the cavity and protrudes out of the cavity by a so-called protrusion thickness, whereby an epitaxial structure is obtained,
c) depositing an encapsulation layer made of a fourth material on the substrate and on the epitaxial structure,
d) carrying out a CMP thinning step to remove the encapsulation layer and the portion of the epitaxial structure protruding from the first main surface of the substrate, the thickness of the deposited encapsulation layer being in the range from 20 to 200% of the protrusion thickness.

2. Method according to claim 1, wherein the thickness of the encapsulation layer is in the range from 20 to 100%, preferably from 20 to 50% of the protrusion thickness.

3. Method according to claim 1, wherein the bottom of the cavity is made of a semiconductor material, preferably monocrystalline, and more preferably of single-crystal silicon.

4. Method according to claim 1, wherein the encapsulation layer is made of silicon oxide, the encapsulation layer being preferably deposited by PECVD.

5. Method according to claim 1, wherein the second material is silicon oxide.

6. Method according to claim 1, wherein the third material is a semiconductor material, preferably germanium or one of its alloys, for example GeSn or SiGe.

7. Method according to claim 1, wherein the substrate comprises a plurality of cavities of different or identical dimensions.

8. Method according to claim 7, wherein the cavities have different dimensions and wherein step b) is carried out until the epitaxial material protrudes out of all cavities.

9. Method according to claim 1, wherein a stop layer, for example made of SiN, is provided in the substrate and wherein the thinning step is stopped when the stop layer is reached.
